(19) United States
(12) Patent Application Publication
(10) Pub. No.: US 2006/0243207 A1
(43) Pub. Date: Nov. 2, 2006

(54) Fluid mixing and delivery system

(76) Inventors: Gregory M. Jursich, Clarendon Hills, IL (US); Rajat Agrawal, Naperville, IL (US); Cyril Bourasseau, Chicago, IL (US)

Correspondence Address: Linda K. Russell, Patent Counsel;Air Liquide, Suite 1800, 2700 Post Oak Blvd., Houston, TX, 77056, US

(21) Appl. No.: 11/267,579

(22) Filed: Nov. 7, 2005

Related U.S. Application Data
(60) Provisional application No. 60/673,183, filed on Apr. 20, 2005.

(51) Int. Cl. C23C 16/00

(52) U.S. Cl. 118/715; 427/248.1

(57) ABSTRACT

A gas mixing and delivery system includes a first gas supply vessel including a first gas stored at a first pressure, a second gas supply vessel including a second gas stored at a second pressure, and a mixing vessel connected to each of the first and second gas supply vessels. The system further includes a buffer tank connected to the mixing vessel to receive a gas mixture including the first and second gases delivered from the mixing vessel. The buffer tank is configured to connect with a process tool. The system is further configured to produce a gas mixture including the first and second gases by facilitating delivery of the first and second gases into the mixing vessel, mixing the first and second gases in the mixing vessel and delivering the gas mixture from the mixing vessel to the buffer tank via a forcing gas that is at a pressure greater than the first pressure.

### CROSS-REFERENCE TO RELATED APPLICATION

This application claims priority from U.S. Provisional Patent Application Ser. No. 60/673,183, entitled “Blending and Delivery System For Vapor Mixtures Involving Low-Pressure Source,” and filed Apr. 20, 2005. The disclosure of this provisional patent application is incorporated herein by reference in its entirety.

### BACKGROUND OF INVENTION

1. Field of Invention

The present invention pertains to blending and delivery of fluid mixtures, in particular gaseous or vapor mixtures, during process applications.

2. Related Art

Many processing applications require mixtures of gases containing two or more gas components. The gas mixtures are typically prepared in advance and supplied to the end-user. In particular, a reliable source of gas mixtures is extremely important in semiconductor processing applications. For example, in manufacturing applications involving technologies such as thin film transistor liquid crystal display (TFT-LCD), light emitting diode (LED), and flat panel display (FPD), a mixture of gases such as phosphine and hydrogen is typically provided for various process steps (e.g., ion doping or deposition). Other examples of process gases include hydrides (e.g., silane, germane, phosphine, and arsine), and Group VIA compounds (e.g., hydrogen selenide and hydrogen sulfide).

Many of these process gases are toxic and corrosive, requiring extreme caution and special considerations for storage and delivery of these gases. Typically, these gases are stored under sub-atmospheric conditions (e.g., by use of an adsorbent inside a container or storage vessel that houses such gases) to prevent their inadvertent release to the surrounding environment. While such sub-atmospheric storage prevents catastrophic release, it is limited for use with pure gases and not to mixtures of gases such as those required for semiconductor processing applications.

Some new precursors are emerging which can be in the form of low vapor pressure liquids. Trisilane is an example which is a liquid having a vapor pressure of 95.5 Torr (0.13 bar) at 0° C. Other examples include tetramethylsilane (4 MS), trisilamine (TSA), and octafluorocyclopentene (C5F8). Typically, these products are stored in cylinders normally used for pressurized gases.

A conventional method for mixing one or more gases from a sub-atmospheric gas source is to withdraw the gas under vacuum and to allow mixing with the other gases under vacuum as they transport along delivery lines to the tool. The mixture concentration can be controlled by adjusting the relative flow rates of the different gases. Conceptually, this approach would appear to be relatively safe and reliable so long as the process tool pressure downstream is maintained significantly less than the source pressure.

However, in reality, piping diameters must be sized larger when delivering gases at sub-atmospheric pressure, thus adding to the cost and space requirements that are necessary for delivering the gas mixtures to the process tool. In addition, the purity of gas mixtures becomes more susceptible to surface desorption and dead volume contamination when delivery is under sub-atmospheric conditions. Further, there is a finite time required for constant, stabilized and steady state flow to be established at the sub-atmospheric conditions, and the highly toxic mixture must be vented and abated prior to establishing acceptable process flow conditions. This increases operating costs, process down time, and safety risks to the overall delivery system.

Further still, implementing a sub-atmospheric gas flow process to existing systems that use pressurized gas mixture sources (i.e., gas mixture sources greater than ambient pressures) would be cost prohibitive, since the delivery lines of the systems would need to be significantly modified (e.g., increasing piping diameters, modifying piping line runs, etc.). In addition, while compressor pumps can be used to form gas mixtures and force the gas mixtures to process sites, they can also contaminate the gases (e.g., with particulate material from the compressor equipment that may become entrained with the gas mixture). Thus, the use of compressor pumps is often not acceptable for use in delivering high purity gas mixtures required for semiconductor processes.

A conventional method for making a mixture utilizing a product stored at above atmospheric pressure is to fill a cylinder or vessel with one gas followed by the addition of a second gas. A precise amount of each gas can be obtained by measuring the gas flow rate using flow meters, weighing the gases using balances and/or monitoring the pressures of the gases. The cylinder is then rolled to make the mixture homogenous. However, there are several problems with this approach. One problem is that the rolling step is labor intensive and time consuming. If rolling were not necessary, analysis for certification of the gas mixture prior to use could be conducted upon filling a manifold, thereby expediting the process. In addition, some emerging semiconductor processing applications require large quantities of gas mixtures, which in turn requires an increasing number of rolling cylinders. Preparation and handling of such a large number of rolling cylinders can be cumbersome and economically prohibitive.

### SUMMARY OF THE INVENTION

It is an object of the present invention to effectively provide gas mixtures in desired amounts and at desired flow rates to a tool or process site.

It is another object of the present invention to provide gas mixtures to a process site while minimizing contamination risks and equipment and operating costs.

It is a further object of the present invention to provide gas mixtures at a variety of different pressures, including sub-atmospheric and/or higher pressures, while minimizing or eliminating the need for mechanical equipment, such as pumps or compressors, to move and mix the gases.

The aforesaid objects are achieved individually and/or in combination, and it is not intended that the present invention be construed as requiring two or more of the objects to be combined unless expressly required by the claims attached hereto.

In accordance with the present invention, a gas mixing and delivery system comprises a first gas supply vessel including a first gas stored at a first pressure, a second gas supply vessel including a second gas stored at a second pressure, and a mixing vessel connected to each of the first and second gas supply vessels so as to receive the first and second gases. The system further comprises a buffer tank connected to the mixing vessel to receive a gas mixture including the first and second gases delivered from the mixing vessel. The buffer tank is configured to connect with a process tool. The system is further configured to produce a gas mixture including the first and second gases by facilitating delivery of the first and second gases into the mixing vessel, mixing the first and second gases in the mixing vessel and delivering the gas mixture from the mixing vessel to the buffer tank via a forcing gas that is at a pressure greater than the first pressure.

In another embodiment of the present invention, a method of producing and delivering a gas mixture for an application comprises delivering a first gas stored at a first pressure to a mixing vessel, delivering a second gas stored at a second pressure to the mixing vessel so as to facilitate mixing of the first and second gases within the mixing vessel to form a gas mixture including the first and second gases, and facilitating forced movement of the gas mixture including the first and second gases from the mixing vessel toward the buffer tank utilizing a forcing gas that is at a pressure greater than the first pressure.

The systems and methods of the present invention facilitate the formation of a gas mixture and delivery of the gas mixture to a buffer tank and process tool without the requirement of a pump, compressor or other mechanical compression device. Further, the gas mixture can be continuously or intermittently delivered to the process tool at a high purity level and with precise concentrations of gaseous components as desired for a particular processing application.

The above and still further objects, features and advantages of the present invention will become apparent upon consideration of the following detailed description of specific embodiments thereof, particularly when taken in conjunction with the accompanying drawings wherein like reference numerals in the figures are utilized to designate like components.

### BRIEF DESCRIPTION OF THE DRAWINGS

FIG. 1 is a diagram of an exemplary embodiment of a gas mixing system combined with a processing tool in accordance with the present invention.

FIG. 2 is a diagram of another exemplary embodiment of a gas mixing system combined with a processing tool in accordance with the present invention.

FIG. 3 is a cross-sectional view of a mixing chamber to mix gases of the system of FIG. 2.

FIG. 4 is a flow chart of process steps for operation of the system of FIG. 2.

FIG. 5 is a diagram of a further exemplary embodiment of a gas mixing system combined with a processing tool in accordance with the present invention.

FIG. 6 is a diagram depicting pressure and concentration of a gas (carbon dioxide) vs. time for a buffer tank including a gas mixture formed utilizing the system of FIG. 2 and in accordance with the present invention.

### DESCRIPTION OF PREFERRED EMBODIMENTS

In accordance with the present invention, a fluid mixing and supply system is provided that is capable of continuously mixing or blending two or more gases at any selected pressures (e.g., sub-atmospheric or higher pressures) and deliver the gas mixture having selected gas compositions at suitable flow rates and pressures to a process tool or site, while ensuring reliability of delivery of the gas mixture and substantially minimizing or preventing gas contamination or the presence of impurities in the gas mixture. In particular, the system facilitates the mixture of at least one gas that is provided from a gas source at sub-atmospheric or above atmospheric pressure conditions while substantially minimizing or preventing impurity contamination of the gas mixture.

The system facilitates the withdrawal of a first gas into a mixing vessel or chamber, followed by introduction of a second gas into the mixing vessel that is at a higher pressure than the first gas. The gases are mixed within the mixing chamber and then delivered to a second chamber or container that stores the gas mixture prior to delivery to a process tool. Thus, the system of the present invention avoids the use of a compressor or pump and/or other forms of mechanical compression, thus ensuring a high level of reliability of the gas mixture purity upon delivery to the process tool or site.

The system of the present invention is particularly suitable for use in providing gas mixtures at suitable concentrations and acceptable purity levels to semiconductor process tools. Any suitable process tool that provides some form of processing for a semiconductor wafer or chip (e.g., structural formation steps, etching, stripping, cleaning, etc.) can be provided in combination with a gas mixture system of the invention. In addition, any combination of gaseous compounds can be provided to form a gas mixture in accordance with the invention including, without limitation, reactive gases such as hydrogen, hydrides (e.g., silane, germane, phosphine, and arsine), Group VIA compounds (e.g., hydrogen selenide and hydrogen sulfide), and Group VIA compounds (e.g., HCl, HF, HBr), and also non-reactive gases such as carbon dioxide, helium and nitrogen.

In particular, the system could be implemented for use in a manufacturing process for forming a semiconductor device. For example, the system may provide a mixture of germane and hydrogen that is created on site at a semiconductor manufacturing facility. In another example, the system may provide a mixture of phosphine and hydrogen for a TFT-LCD manufacturing application. As noted above, many gases used in semiconductor manufacturing processes, such as thin film formation processes, are toxic and are stored at sub-atmospheric pressure conditions to prevent inadvertent release of such gases from a process system. Such gases can be processed and pressurized safely while preventing contamination with the system of the invention.

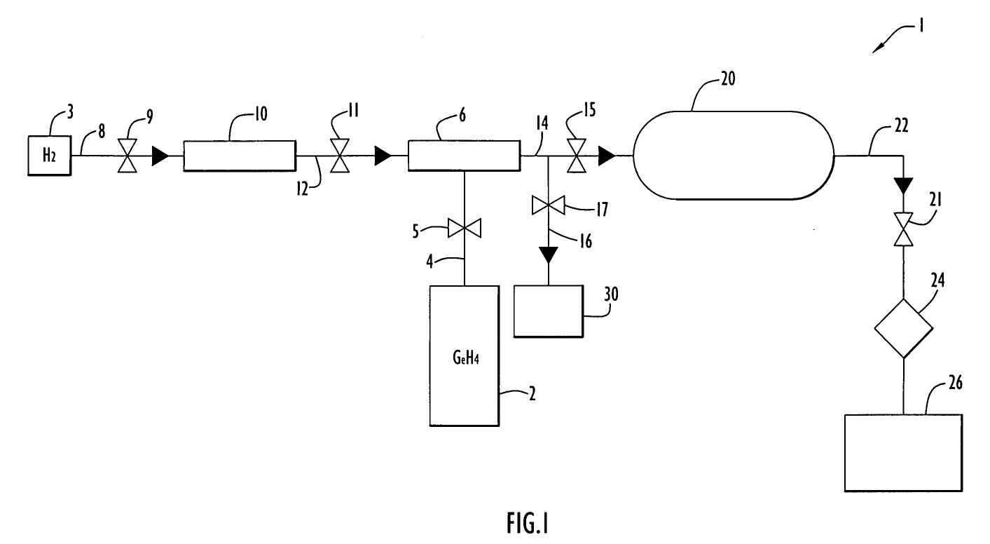

An exemplary embodiment of a system that provides a mixture of germane (GeH₄) and hydrogen (H₂) to a semiconductor process tool is depicted in FIG. 1. It is noted that these two gases are cited for exemplary purposes only, and the system of FIG. 1 (as well as each of the other systems described below) is applicable to any combination of gases or other fluids. System 1 includes a storage container or vessel 2 containing GeH₄ at sub-atmospheric pressure conditions (e.g., no greater than about 1 bar). Vessel 2 is connected, via a suitable piping line 4, to an inlet of a mixing vessel 6. A valve 5 is disposed along line 4, to control the flow of GeH₄ to the mixing vessel. A supply source 3 provides a supply of H₂, via a suitable piping line 8, to an inlet of a storage vessel 10. A valve 9 is disposed along line 8 to control the flow of hydrogen to vessel 10. An outlet of H₂ storage vessel 10 is connected, via a suitable piping line 12, to another inlet of mixing vessel 6. A valve 11 is disposed along line 12 to control the flow of hydrogen from vessel 10 to the mixing vessel.

A gas mixture storage vessel or buffer tank 20 is disposed downstream from the mixing vessel 6, and an outlet of the mixing vessel is connected to an inlet of the buffer tank via a suitable piping line 14. A valve 15 is disposed along line 14 to control the flow of the gas mixture formed in the mixing vessel to the buffer tank. The buffer tank further includes an outlet connected to a suitable piping line 22 that leads to a semiconductor process tool 26, with a valve 21 disposed along the line 22 to control the flow of the gas mixture from the buffer tank to the process tool. A filter 24 is also disposed along line 22 to filter any particulate material or other impurities that may be present in the gas mixture prior to delivery of the gas mixture to the process tool. The filter can have any suitable mesh or screen size to filter particulate material of selected sizes from the gas mixture.

A vacuum line 16 is also connected to piping line 14 at a location upstream from valve 15, and the vacuum line includes a valve 17 disposed along this line. Vacuum line 16 connects with a negative pressure generator or suction source 30 (e.g., a compressor) to facilitate the generation of a vacuum or pressure differential between mixing vessel 6 and GeH₄ storage vessel 2 so as to draw GeH₄ gas into the mixing vessel. It is noted that the suction source can also be used to purge buffer tank 20 as desired (i.e., by opening valve 15) and at selected times during system operation.

In operation, valve 9 is opened and a selected amount of hydrogen is delivered into vessel 10 by facilitating the flow of hydrogen until a suitable pressure within this vessel is obtained. The pressure within vessel 10 can be monitored via a pressure and/or temperature sensor connected in any suitable manner with the vessel (or piping line associated with the vessel). Upon achieving a selected pressure within vessel 10, valve 9 is closed. Given the known volume, temperature and pressure of vessel 10, a precise quantity of H₂ gas in vessel 10 is also known. Valve 11 remains closed until the hydrogen gas is to be delivered for mixing with GeH₄ gas in mixing vessel 6.

Vacuum is established in vessel 6 by opening the valve 17 (while valves 5, 11, 15 remain closed). Once a sufficient vacuum is reached within vessel 6 (e.g., by measuring a pressure at any suitable location within vessel 6), valve 17 is closed. The GeH₄ gas is delivered from vessel 2 and into mixing vessel 6 by opening valve 5 (while valves 11 and 15 remain closed). The pressure and/or temperature of the mixing vessel is monitored via one or more suitable sensors connected with the mixing vessel (or any suitable piping line connected with the mixing vessel), such that a precise amount of GeH₂ gas is provided within this vessel. Once a selected pressure within the mixing vessel is achieved and is maintained, valves 5 and 17 are closed, and valve 11 is opened to permit flow of H₂ gas from vessel 10 into mixing vessel 6. The pressure of H₂ in vessel 10 is much greater than the pressure of GeH₄ in mixing vessel 6, so the H₂ gas flows into the mixing vessel and mixes with the GeH₄ gas. Valve 15 is also opened to permit the flow of the gas mixture to buffer tank 20. The pressure within buffer tank 20 is less than the pressure of the gas mixture in mixing tank 6, so as to permit the gas mixture to flow to the buffer tank. Valve 21 is selectively manipulated to open and closed positions to direct the gas mixture through filter 24 and to process tool 26 at any desired flow rate and pressure. Each of the mixing vessel 6, H₂ storage vessel 10 and buffer tank 20 can be filled as necessary to form a gas mixture and direct the gas mixture to the buffer tank by repeating the operational steps as described above so as to provide a continuous flow of the gas mixture to the process tool.

The concentrations of GeH₄ and H₂ in the gas mixture are determined based upon the volumetric sizing of vessels 6 and 10 and the pressures at which each gas is initially provided to each vessel. For example, given a set volume V₁ of H₂ storage vessel 10 and a set volume V₂ of mixing vessel 6 which initially contains GeH₄ (i.e., before mixing occurs), the pressure P₁ of vessel 10 and the pressure P₂ of mixing vessel 6 can be selected so as to obtain the desired concentration of GeH₄ in the resultant gas mixture. When the temperature of both vessels is similar or about the same, the molar concentration of GeH₄ in the resultant gas mixture that flows to buffer tank 20 is defined as P₂V₂/(P₁V₁+P₂V₂−P_{1f}V₁−P_{2f}V₂), where P_{1f} and P_{2f} are the final pressures in vessel 10 and vessel 6, respectively, after the gas mixture has been delivered to the buffer tank. For higher pressures where ideal gas laws do not apply, correction factors based on gas compressibility can be used to obtain more accurate results for gas concentrations.

Thus, the system of FIG. 1 provides for an effective mixing between a first gaseous compound (e.g., at sub-atmospheric pressure conditions) and a second gas that is at a higher pressure than the first gas, without the requirement of utilizing a pump to force the mixing or flow of gases to the buffer tank and process tool. The pressure of H₂ gas provides the force for directing the gas mixture from the mixing vessel to the buffer tank.

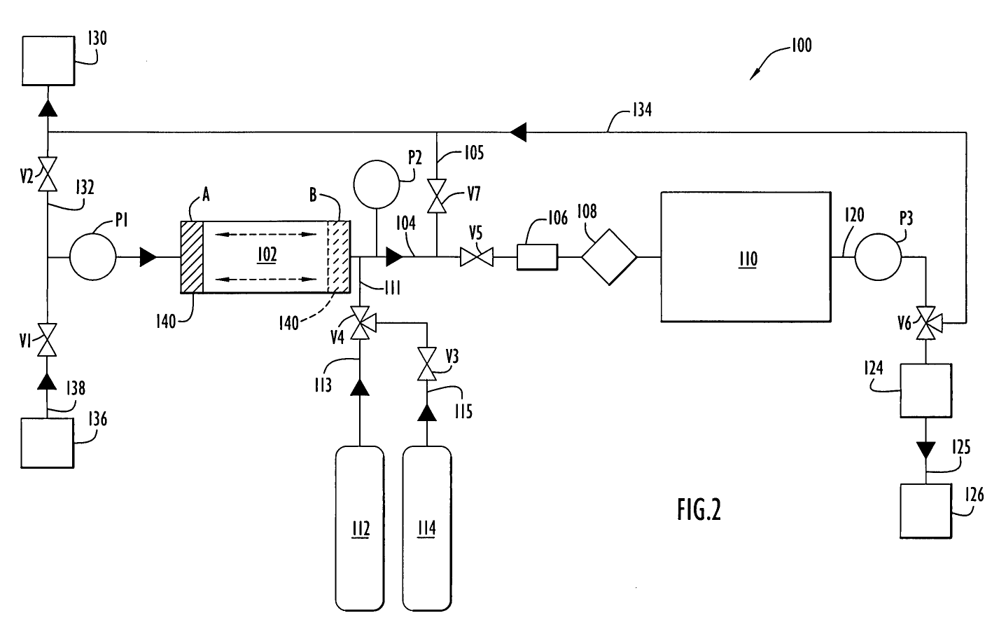

Another embodiment of a gas mixing system combined with a process tool is depicted in FIG. 2. System 100 includes an elongated mixing vessel 102 including longitudinal ends A and B with openings disposed at such ends to facilitate an inlet and/or outlet for the mixing vessel. The mixing vessel is connected (at its longitudinal end B) with an inlet of a buffer tank 110 via a suitable piping line 104. A valve V5, a mixing unit 106, and a filter 108 are all disposed along piping line 104, where the mixing unit 106 is disposed between the valve V5 and the filter 108, and the filter 108 is disposed between the mixing unit and buffer tank 110. The mixing unit can be of any suitable type (e.g., a static mixer disposed within a suitable housing) to facilitate mixing of two or more fluids passing through the unit, and the filter can also be of any suitable type to facilitate separation of particulate materials of any suitable sizes from the gas mixture flowing through the filter.

A pair of gas supply vessels 112 and 114 are connected via suitable piping lines 111, 113 and 115 to line 104 at a location between valve V5 and mixing vessel 102. In particular, piping line 113 connects with line 104 to a three-way valve V4, and piping line 113 extends from vessel 112 to one end of three-way valve V4. Piping line 115 extends from vessel 114 to another end of three-way valve V4, and a valve V3 is disposed along line 115. A pressure sensor P2 is connected to line 104 at a location proximate mixing vessel 102 and between line 111 and valve V5.

Piping lines 120 and 125 connect a process tool 126 with an outlet of buffer tank 110. Piping line 120 extends from the outlet of buffer tank 120 to one end of a three-way valve V6, and a pressure sensor P3 is disposed along line 120. Piping line 125 extends from another end of three-way valve V6 to process tool 126, and a mass flow controller (MFC) 124 is disposed along line 125. The process tool is preferably a semiconductor processing tool that performs any one or more types of process steps for a semiconductor component (e.g., forming substrate layers, stripping, etching, cleaning, etc.).

A negative pressure generator or suction source 130 is connected to mixing vessel 102 (at longitudinal end A of the vessel) via a suitable piping line 132, and a valve V2 is disposed along the piping line 132. In addition, a pressure sensor P1 is disposed along line 132 between valve V2 and mixing vessel 102. A suitable piping line 134 connects to a portion of line 132 between suction source 130 and valve V2 and further extends to and connects with an end of three-way valve V6 located in line 120 between buffer tank 110 and process tool 126. As described in greater detail below, the suction source 130 is connected within system 100 to generate a negative pressure between the suction source and the mixing vessel 102 and also between the suction source and the buffer tank 110.

Optionally, a suitable piping line 105 is provided to directly connect piping line 104 (at a location upstream from valve V5) to piping line 134. This connection allows system 100 to generate a vacuum within vessel 102, via suction source 130, independent of the buffer tank 110.

A gas supply source 136 (e.g., a storage tank or vessel) houses an inert gas (e.g., nitrogen or helium) that is used to purge gases from the system as well as to force mixing and delivery of the process gases to the buffer tank as described below. The gas supply source 136 is connected to line 132 via a suitable piping line 138 and at a location between valve V2 and pressure sensor P1. A valve V1 is disposed along line 138 to control the flow of the inert gas to the mixing vessel 102.

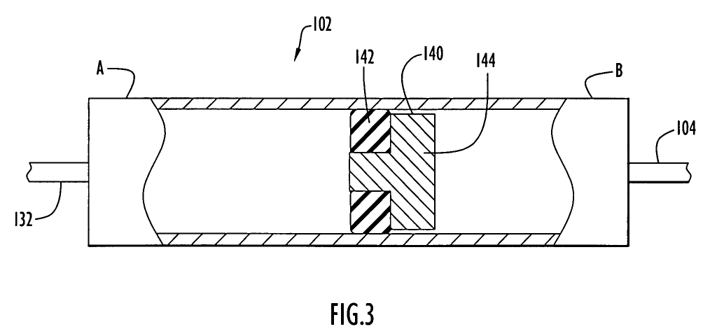

An interior portion of mixing vessel 102 is shown in FIG. 3 and includes a movable sealing disc 140 secured within the vessel. The sealing disc 140 includes a spring-energized seal 142 that is suitably dimensioned and biased radially outward (e.g., via one or more springs) to frictionally engage and provide a fluid-tight seal with an interior wall surface section of the mixing vessel 102 while permitting longitudinal movement of the disc within and between ends A and B of mixing vessel 102. A rigid support member 144 is secured to one side and extends through a portion of the seal 142 to provide structural support for the disc during movement within the mixing vessel as described below. Thus, disc 140 defines a pair of sub-chambers within mixing vessel 102 that change in volume as the disc is moved toward longitudinal end A or longitudinal end B of the mixing vessel (as shown in FIG. 2 by the dashed lines and arrows within mixing vessel 102), and any gas or gases and/or other fluids disposed within either sub-chamber are forced into the piping line at either end of the vessel and prevented from flowing to the other sub-chamber due to the fluid-tight seal provided by the disc.

The gas supply vessels 112 and 114 contain the gases that are mixed within vessel 102 and are delivered to the buffer tank and process tool. Any types of gases can be provided in vessels 112 and 114, including pressurized gases as well as gases at sub-atmospheric pressure conditions (e.g., below 1 bar). In a preferred embodiment, vessel 112 includes a gaseous compound A that is stored at pressures ranging from about 0.01 bar to about 100 bar, preferably in the range of about 0.1 bar to about 50 bar. Examples of compounds that can be stored in vessel 112 include hydrates such as germane, silane and phosphine. For example, germane can be stored at a sub-atmospheric pressure of about 0.8 bar or lower, where an adsorbent is provided to maintain sub-atmospheric pressure conditions within the vessel, and phosphine can be stored at pressures of about 0.1 bar to about 40 bar. Other examples of gases that can be stored in vessel 112 and have low vapor pressures and/or are stored at low pressures include, without limitation, boron trichloride, boron trifluoride, halocarbons, hydrogen fluoride, and tungsten fluoride. Other compounds having low vapor pressures and that include liquid precursors can also be stored in vessel 112, such as trimethylsilane and trisilane.

Vessel 114 stores a gaseous compound B that can be an inert gas, such as nitrogen or helium or, alternatively, a reactive gas such as hydrogen. Gaseous compound B is stored in vessel 114 at a pressure that is preferably greater than the pressure at which gaseous compound A is stored. Preferably, gaseous compound B is stored within vessel 114 in the range of about 0.1 bar to about 300 bar, and more preferably in the range of about 1 bar to about 200 bar.

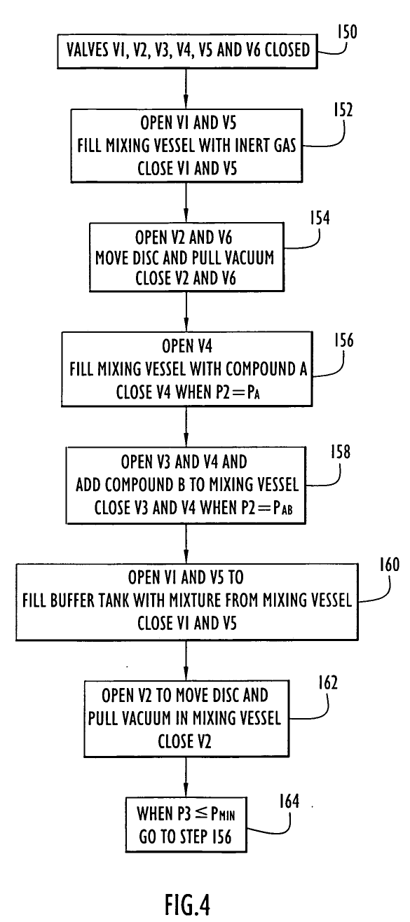

Operation of system 100 is described with reference to FIGS. 2 and 3 as well as the flowchart depicted in FIG. 4. All valves V1-V6 are initially closed within system 100 (step 150), and sealing disc 140 is located at end A within mixing vessel 102. It is noted that valve V4 is initially closed to prevent fluid communication between line 111 and each of lines 113 and 115, while valve V6 is initially closed to prevent fluid communication between line 120 and each of lines 125 and 134. Valves V1 and V5 are then opened (step 152), and inert gas from gas supply source 136 enters mixing vessel 102 via lines 138 and 132. Optionally, a pressure regulator is provided at or near supply source 136 to control the pressure and flow of the inert gas within the system. As the inert gas enters the mixing vessel, sealing disc 140 is moved from end A toward end B of the mixing vessel, which forces any gases out of the mixing vessel and into piping line 104 toward buffer tank 110.

Alternatively, in embodiments in which piping line 105 and valve V7 are provided, valve V7 can be opened while valve V5 remains closed. In this scenario, the suction or vacuum is applied via line 105 (thus bypassing buffer tank 110), and any gases forced out of the mixing vessel flow through line 105 to line 134 and then to the suction source 130.

After a selected time period and/or when a predetermined pressure has been reached (as measured by sensor P1) and the sealing disc has been moved to end B within the mixing vessel (as shown by disc 140 in dashed lines within the mixing vessel), valves V1 and V5 are closed. Valves V2 and V6 are then opened (step 154), where three-way valve V6 is opened to permit fluid communication between lines 120 and 134. Suction source 130 is activated to generate a negative pressure or vacuum within mixing chamber 102 so as to withdraw the inert gas through end A of the mixing chamber and through line 132 to the vacuum source. In addition, the vacuum pulls sealing disc 140 back to end A within the mixing chamber. Any gases within line 104 (between valve V5 and the buffer tank) and buffer tank 110 are also withdrawn through lines 120 and 134 to suction source 130. Once a selected vacuum has been reached within the system (e.g., as determined by pressure sensor P1 and/or pressure sensor P3), valves V2 and V6 are closed, leaving the mixing vessel at sub-ambient pressure conditions (i.e., pressures no greater than about 1 bar) to facilitate the flow of gas from vessel 112 into this vessel without the requirement of any mechanical device. The withdrawn gases delivered to vacuum source 130 can be collected and delivered to a suitable storage or processing location.

Alternatively, it is noted that sealing disc 140 can also be moved back to end A of the mixing vessel by opening three-way valve V4 to permit gas from vessel 114 to flow from line 115 into line 111 and into the mixing vessel at end B. After the disc 140 is moved to end A within vessel 102, suction source 130 can then be activated and valves V5 and V6 opened (where V6 is operated in the manner described above to provide fluid communication between lines 120 and 134) to facilitate the withdrawal of any gases within the system between mixing vessel 102 and buffer tank 110 into piping line 134 and to suction source 130. In this embodiment, the sealing disc is suitably designed and/or the vacuum or negative pressure is selected such that the disc resists and is substantially prevented from moving from its location at end A toward end B within the mixing vessel when a vacuum is established within the mixing vessel by the suction source.

In the next step, three-way valve V4 is opened (step 156) to permit fluid communication between lines 113 and 111, such that gaseous compound A flows from vessel 112 into mixing vessel 102. The pressure within the mixing vessel is monitored via sensor P2. Upon reaching a selected pressure P_{A} within the mixing vessel (e.g., in a range of about 0.01 bar to about 20 bar, preferably about 0.1 bar to about 5 bar), valve V4 is closed. Next, valves V3 and V4 are opened (step 158), where three-way valve V4 is opened such that line 115 is in fluid communication with line 111, to permit gaseous compound B to flow from vessel 114 into mixing vessel 102. The valves remain open until the pressure within the mixing vessel reaches a selected pressure P_{AB} (about 0.5 bar to about 20 bar, preferably about 1 bar to about 5 bar). A suitable device such as a pressure regulator can also be provided at a suitable location along line 115 and/or at an outlet of storage vessel 114 to reduce the pressure of gaseous compound B prior to delivery to the mixing vessel. When the pressure within the mixing vessel reaches a selected value, valves V3 and V4 are closed.

The concentrations of gaseous compounds A and B within the mixing vessel can be precisely controlled by monitoring the pressure within the mixing vessel during the addition of each gas. For example, if it is desired to provide a mixture of these gases with a 10% molar concentration of gaseous compound A, the pressure values can be selected such that P_{A} is 0.1 bar and P_{AB} is 1 bar. It is further noted that any other suitable devices (e.g., flow controllers and/or flow meters) can be provided as an alternative or in combination with one or more pressure sensors to precisely determine and control the concentration of gases provided to the mixing vessel.

Upon achieving the desired concentrations of gases within mixing vessel 102, valves V1 and V5 are opened (step 160), and inert gas is directed from source 136 through lines 138 and 132 into the mixing vessel at end A of the vessel. The pressure of the inert gas flowing into the mixing vessel from source 136 is controlled (e.g., by monitoring pressure sensor P1 and controlling valve V1) so as to force sealing disc 140 toward end B of the mixing vessel, which in turn forces gaseous compounds A and B out of the mixing vessel at end B of the vessel and toward buffer tank 110. The combination of gaseous compounds A and B are directed through mixing unit 106 and filter 108, where they are suitably mixed together and any particulate materials are removed from the gases.

Once sealing disc 140 has reached end B of mixing vessel 102, a transfer of the gas mixture from the mixing vessel to the buffer tank is complete. Valves V1 and V5 are then closed, and valve V2 is opened (step 162) and the suction source activated to generate a vacuum within mixing vessel 102 so as to pull sealing disc 140 back toward end A of the mixing vessel and withdraw the inert gas to the suction source, while creating a vacuum within the mixing vessel to facilitate withdrawal of gas from vessel 112 at sub-ambient pressures (i.e., pressures no greater than about 1 bar) in another successive gas mixing step.

The pressure within buffer tank 110 is continuously monitored by pressure sensor P3. In particular, the pressure of the gas mixture within the buffer tank is preferably maintained within a range of about 0.1 bar to about 20 bar, more preferably within a range of about 1 bar to about 10 bar. The buffer tank delivers the gas mixture to process tool 126 by manipulating valve V6 such that line 120 is in fluid communication with line 125. Mass flow controller 124 controls the flow of the gas mixture to the process tool. When the pressure within the buffer tank falls below a minimum or threshold pressure value Pₘᵢₙ (step 164), the process steps described above (steps 156-164) for generating and providing a mixture of gaseous compounds A and B at precise concentrations to the buffer tank are repeated.

Thus, system 100 is capable of providing a continuous supply of the gas mixture at precise concentrations and at high purity levels to the process tool during system operation. By using a suction source to generate a vacuum in the system and also an inert gas to force the process gas mixture from the mixing vessel to the buffer tank, gases (including one or more gases at sub-atmospheric storage conditions) are delivered without the requirement of mechanical devices (e.g., pumps). This ensures the quality and purity of the gas mixture to be used in the process tool.

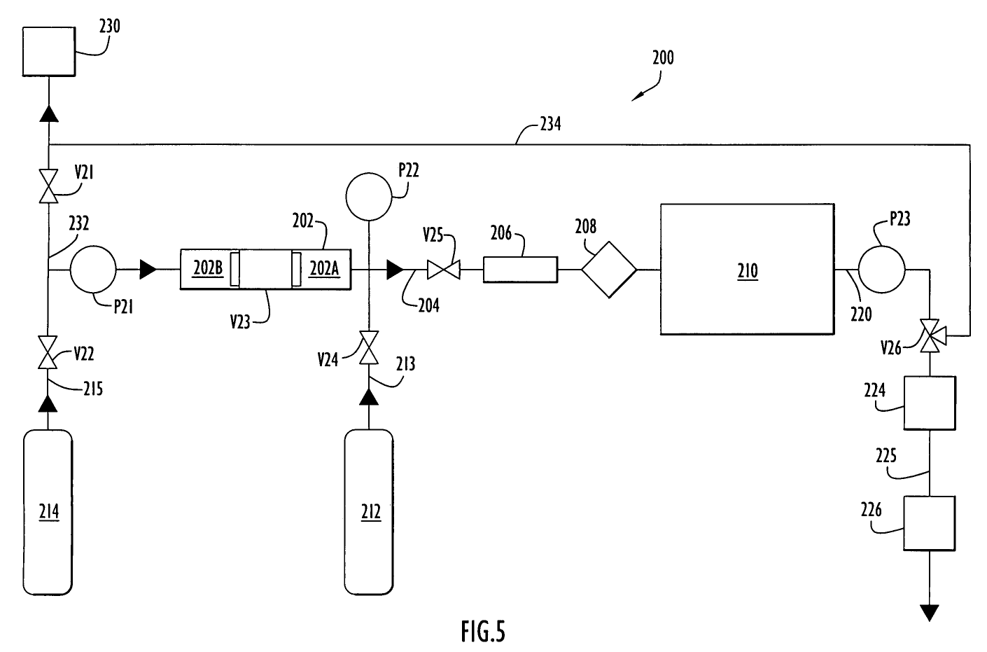

In a modification to the previously described system, the inert gas used to push or force the gas mixture from the mixing vessel can be eliminated, and one of the gases that makes up a portion of the gas mixture also forces the gas mixture from the mixing vessel to the buffer tank. Referring to FIG. 5, a system 200 is depicted in which an elongated mixing vessel 202 includes sub-chambers 202A and 202B extending to opposing longitudinal ends of the mixing vessel. The mixing vessel also includes openings at the longitudinal ends of the vessel that serve as inlets and/or an outlets for the vessel. The sub-chambers 202A and 202B are separated from each other by a valve V23. Valve V23 can be any suitable valve (e.g., a ball valve) that can be manipulated to one position that provides a fluid tight seal between the two sub-chambers and to another position that permits fluid communication between the two sub-chambers. Preferably, valve V3 includes a movable orifice opening that is substantially the same or similar dimension or dimensions as the cross-sectional dimensions of the sub-chambers and is further configured to minimize pressure drop across the valve.

A negative pressure generator or suction source 230 is connected via a suitable piping line 232 to mixing vessel 202 at the longitudinal end including sub-chamber 202B. A valve V21 is disposed along line 232, and a pressure sensor P21 is also disposed along line 232 at a location between valve V21 and the mixing vessel.

Mixing vessel 202 is further connected, via a suitable piping line 204, to a buffer tank 210. A pressure sensor P22, valve V25, mixing unit 206 and filter 208 are all disposed along line 204. In particular, pressure sensor P22 is disposed between the mixing vessel and valve V25, the valve V25 is disposed between pressure sensor P22 and mixing unit 206, and filter 208 is disposed between mixing unit 206 and buffer tank 210. As in the previous embodiment, the mixing unit can be of any suitable type (e.g., a static mixer disposed within a suitable housing) to facilitate mixing of two or more fluids passing through the unit, and the filter can also be of any suitable type to facilitate separation of particulate materials of any suitable sizes from the gas mixture flowing through the filter.

Piping lines 220 and 225 connect a process tool 226 with an outlet of buffer tank 210. In particular, piping line 220 extends from the outlet of buffer tank 220 to one end of a three-way valve V26, and a pressure sensor P23 is disposed along line 220. Piping line 225 extends from another end of three-way valve V26 to process tool 226, and a mass flow controller (MFC) 224 is disposed along line 225. The process tool is preferably any semiconductor processing tool that performs one or more selected types of conventional or other process steps for a semiconductor component such as those noted above for the previous embodiment.

A suitable piping line 234 connects to a portion of line 232 between suction source 230 and valve V21 and further extends to and connects with an end of three-way valve V26 located in line 220 between buffer tank 210 and process tool 226.

As in the embodiment described above and depicted in FIG. 2, system 200 includes a pair of gas supply vessels 212 and 214. The gas supply vessels contain the gases that are mixed within vessel 202 and are delivered to the buffer tank and process tool. Vessel 212 connects with line 204 via a suitable piping line 213, such that this vessel can deliver a gas directly to sub-chamber 202A of the mixing vessel. A valve V24 is disposed along line 213 to facilitate selective flow of gas from vessel 212 to sub-chamber 202A. Vessel 214 connects with line 232 via a suitable piping line 215 and at a location between valve V21 and pressure sensor P21, such that this vessel can deliver a gas directly to sub-chamber 202B of the mixing vessel. A valve V22 is disposed along line 215 to facilitate selective flow of gas from vessel 212 to sub-chamber 202B.

As in the previous embodiment, any types of gases can be provided in vessels 212 and 214, including pressurized gases as well as gases at sub-atmospheric pressure conditions (e.g., below 1 bar) and including, without limitation, any of the exemplary gases that are described above. In a preferred embodiment, vessel 212 includes a gaseous compound A that is stored at pressures ranging from about 0.01 bar to about 100 bar, preferably in the range of about 0.1 bar to about 50 bar, while vessel 214 includes a gaseous compound B that is stored at pressures ranging from about 0.1 bar to about 300 bar, and preferably in the range of about 1 bar to about 200 bar. Most preferably, gaseous compound A is maintained in vessel 212 at a lower pressure than the pressure at which gaseous compound B is maintained in vessel 214.

In operation, all of the valves V21-V26 in system 200 are initially closed, with three-way valve V26 preventing fluid communication of line 220 with each of lines 234 and 225. Valves V21 and V23 are opened and suction source 230 is activated to generate a vacuum within both sub-chambers 202A and 202B of the mixing vessel, such that any gases within the sub-chambers are evacuated and drawn through line 232 to the suction source. Optionally, three-way valve V26 can also be opened to facilitate fluid communication between line 220 and line 234 so as to evacuate any gases that may be present within buffer chamber 210. After a desired vacuum level is achieved within the mixing vessel and/or the buffer chamber (as determined by pressure sensor P21 and/or pressure sensor P23), valves V21, V23 and V26 are closed, such that sub-chambers 202A and 202B are separated from each other via closed valve V23 and the sub-chambers are at selected sub-ambient pressure conditions and, in particular, below the pressure of each of gaseous compounds A and B stored within vessels 212 and 214.

Valve V24 is then opened to permit gaseous compound A to flow from vessel 212) through lines 213 and 204 into sub-chamber 202A (which is at a lower pressure than vessel 212). Once a suitable pressure is obtained within sub-chamber 202A (as measured by pressure sensor P22), a precise amount of gaseous compound A is in the mixing vessel (i.e., the precise amount of gas is determined based upon the measured pressure and the known volume of the sub-chamber). The amount of gaseous compound A that is added to the mixing vessel can also be determined utilizing a suitable flow meter disposed, for example, along line 213. Valve V24 is then closed, and valve V22 is opened to permit gaseous compound B to flow from vessel 214 through lines 215 and 232 into sub-chamber 202B. A precise amount of gaseous compound B is provided to sub-chamber 202B upon reaching a suitable pressure within this sub-chamber (as measured by pressure sensor P21), and valve V22 is then closed. It is further noted that gaseous compounds A and B can be delivered to their respective sub-chambers at about the same time to reduce processing time for achieving a desired gas mixture.

Once the predetermined amounts of gaseous compounds A and B are delivered to sub-chambers 202A and 202B and valves V22 and V24 are closed, valves V23 and V25 are opened (e.g., simultaneously or, alternatively, V23 is opened first followed by V25) to permit mixing of gaseous compounds A and B within mixing vessel 202 and delivery of the gases through line 204, mixing unit 206, and filter 208 and into buffer tank 210. As noted above, gaseous compound B is provided at a greater pressure than gaseous compound A within the mixing vessel. Thus, when valve V23 is opened, gaseous compound B flows from sub-chamber 202B into 202A to mix with gaseous compound A and further force the two gases into line 204 toward the buffer tank. Mixing unit 206 further mixes the two gaseous compounds together, while filter 208 removes particulate material of selected dimensions from the gas mixture prior to entering buffer tank 210.

Prior to opening valve V23, the pressure of gaseous compound B (as measured by pressure sensor P21) is preferably about 1.01 to about 2.5 times the pressure of gaseous compound A (as measured by pressure sensor P22). Alternatively, the pressures of the gases can be selected such that the gas mixture leaving the mixing vessel is within the laminar flow region as determined by the Reynold's Number or N_{Re,} where N_{Re} is defined as:
N_{Re}=D*G/μ
where D is the internal diameter of the vessel/pipe where flow is being characterized, G is the mass velocity of the gas, and μ is the fluid viscosity. In particular, the N_{Re} value of gaseous compound B flowing through valve V23 is preferably less than 10,000, more preferably less than 2,000.

After a predetermined period of time and/or a selected pressure within buffer tank 210 is reached (as measured by pressure sensor P23), the gas mixture including all of gaseous compound A has been delivered to the buffer tank, and valve V25 is closed. The above steps of filling mixing vessel 202 with gaseous compounds A and B and delivering the gases to the buffer tank can be repeated as necessary to achieve and maintain a desired pressure level of the gas mixture within the buffer tank during system operation. Valve V26 is opened to facilitate fluid communication between line 220 and line 225, and the gas mixture from the buffer tank is directed to process tool 226, where the flow rate of the gas mixture to the process tool is controlled by mass flow controller 224. Thus, the system of FIG. 5 can provide a mixture of gases to the process tool continuously or, alternatively, intermittently based upon a particular application.

All of the previously described systems can also be automatically controlled, via one or more suitable controllers that are in communication with the various pressure sensors, mass flow controllers, valves, etc., so as to selectively and automatically control the generation of a suitable gas mixture at desired flow rates and delivery of gas mixtures at the required capacity for effective operation of one or more process tools. Further, while the systems all describe the formation of a mixture of two gaseous compounds, it is noted that the invention can also effectively provide mixtures of any suitable number of gaseous compounds (e.g., three or more compounds) to any suitably number of process tools (e.g., one, two or more process tools) for any selected number of different applications. Gas mixtures are formed with at least one reactive gas that is provided at a selected pressure (e.g., sub-atmospheric and/or other pressures), and at least one other gas that can be inert or reactive and is preferably at a greater pressure than the reactive gas with which it is to be mixed.

In an example utilizing the system described above and depicted in FIGS. 2-4, a gas mixture of carbon dioxide (a reactive, gaseous compound A) and helium (an inert, gaseous compound B) were blended in mixing vessel 102. Carbon dioxide was initially added to the mixing vessel from vessel 112 at a pressure of 100 Torr (0.133 bar), followed by the addition of helium at a much higher pressure from vessel 114. For example, helium can be provided at a pressure of about 1900 Torr (2.53 bar). A supply of helium was then added from vessel 136 to longitudinal end A of the mixing vessel, so as to force sealing disc 140 toward end B of the mixing vessel, which in turn forced the carbon dioxide/helium mixture to buffer tank 110. The sealing disc 140 was then moved back to end A of the mixing vessel in the manner described above, and the steps of re-filling the mixing vessel with carbon dioxide and helium and delivering the mixture to the buffer tank was repeated several times until a pressure of 1840 Torr (2.45 bar) was reached within the buffer tank. Upon reaching the desired pressure within the buffer tank, the gas mixture was permitted to flow from the buffer tank to a carbon dioxide analyzer that monitored the CO₂ concentration in the gas.

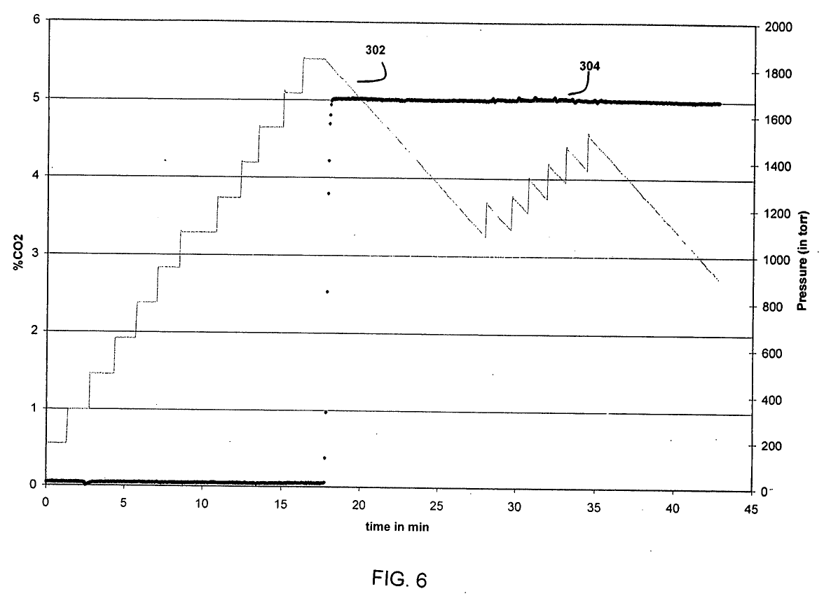

The data plotted in FIG. 6 shows the measured pressure within the buffer tank (right side of y-axis) vs. time (x-axis) as the buffer tank is filled with the gas mixture and during removal of the gas mixture from the buffer tank. The measured pressures are referenced as data 302 in FIG. 6. In addition, the measured CO₂ concentration (left side of y-axis) vs. time is also plotted in FIG. 6 as data 304. Withdrawal of the gas mixture from the buffer tank occurred at about t=17.6 minutes in the plotted data (as can be seen from the sudden jump in plotted CO₂ concentration), which resulted in a steady and continuous drop in buffer tank pressure. When the buffer tank pressure reached a minimum value of 1080 Torr (1.44 bar), the repetitive process of supplying a carbon dioxide/helium mixture to the buffer tank was continued (as can be seen in the stepped pressure increase starting at about t=28 minutes) until the selected pressure level of 1840 Torr (2.45 bar) was again reached. As can be seen from the plotted data 304, the CO₂ concentration as measured by the analyzer remained constant during this refilling process, indicating that the system was capable of providing the gas mixture at a substantially continuous flow rate throughout the process of delivering gas mixtures from the mixing vessel to the buffer tank.

Thus, the systems and corresponding methods of the present invention provide gas mixtures (including gaseous compounds that are stored at sub-atmospheric pressure conditions) without the requirement of a compressor, pump or any other mechanical device to mix and move the gases. The gas mixtures can be provided continuously or intermittently to one or more process tools for a variety of applications, where the gas mixtures are provided in precise amounts, at precise concentrations while preventing or substantially minimizing contamination of the mixtures during mixing and delivery. The buffer tank allows the gas mixtures to be stored for any select time period prior to usage. Further, the systems prevent or substantially minimize the venting of waste gases, which is very beneficial in applications in which expensive and/or toxic gaseous compounds are used.

Having described novel fluid mixing and delivery systems and methods for mixing and delivering fluids, it is believed that other modifications, variations and changes will be suggested to those skilled in the art in view of the teachings set forth herein. It is therefore to be understood that all such variations, modifications and changes are believed to fall within the scope of the present invention as defined by the appended claims.

1. A gas mixing and delivery system comprising:
a first gas supply vessel including a first gas stored at a first pressure;
a second gas supply vessel including a second gas stored at a second pressure;
a mixing vessel connected to each of the first and second gas supply vessels so as to receive the first and second gases; and
a buffer tank connected to the mixing vessel so as to receive a gas mixture including the first and second gases delivered from the mixing vessel, the buffer tank being configured to connect with a process tool;
wherein the system is configured to produce a gas mixture including the first and second gases by facilitating delivery of the first and second gases into the mixing vessel, mixing the first and second gases in the mixing vessel and delivering the gas mixture from the mixing vessel to the buffer tank via a forcing gas that is at a pressure greater than the first pressure.

2. The system of claim 1, wherein the system facilitates forming the gas mixture with a selected concentration of each of the first and second gases by delivering each of the first and second gases into the mixing vessel until a selected pressure is reached within the mixing vessel.

3. The system of claim 1, further comprising:
a sealing member disposed within the mixing vessel and configured to be movable within and between a first end and second end of the mixing vessel while maintaining a sealing engagement with interior wall surface portions of the mixing vessel; and
a forcing gas supply vessel including the forcing gas that is at a third pressure that is greater than the first and second pressures, wherein the forcing gas supply vessel is connected proximate the first end of the mixing vessel;
wherein the system provides the forcing gas at a selected pressure to the mixing vessel so as to force the sealing member to move from the first end of the mixing vessel toward the second end of the mixing vessel and to force the gas mixture including the first and second gases from the second end of the mixing vessel and to the buffer tank.

4. The system of claim 3, further comprising:
a vacuum source connected with the first end of the mixing vessel and configured to generate a pressure differential within the mixing vessel so as to pull the sealing member from the second end of the mixing vessel toward the first end of the mixing vessel.

5. The system of claim 1, wherein the second gas is the forcing gas that forces the gas mixture including the first and second gases to the buffer tank.

6. The system of claim 5, wherein the mixing vessel includes a first sub-chamber configured to receive the first gas, a second sub-chamber configured to receive the second gas, and a valve disposed between the first and second sub-chambers that is adjustable between a first position and a second position, the first valve position isolates and prevents movement of gases between the first and second sub-chambers, and the second valve position facilitates fluid communication between the first and second sub-chambers.

7. The system of claim 1, further comprising:
a vacuum source connected with the mixing vessel and configured to selectively evacuate gases from the mixing vessel during activation of the vacuum source such that the mixing vessel has a pressure that is less than each of the first and second gases.

8. The system of claim 7, wherein the first gas supply vessel is configured to store the first gas such that the first pressure is no greater than about 1 bar.

9. The system of claim 7, wherein the vacuum source is further connected with the buffer tank and is further configured to selectively evacuate gases from the buffer tank during activation of the vacuum source.

10. The system of claim 1, further comprising:
a filter disposed between the mixing vessel and the buffer tank.

11. The system of claim 1, further comprising:
a mixing unit disposed between the mixing vessel and the buffer tank, wherein the mixing unit facilitates further mixing of the first and second gases of the gas mixture prior to delivery of the gas mixture to the buffer tank.

12. A method of producing and delivering a gas mixture for an application, the method comprising:
delivering a first gas stored at a first pressure to a mixing vessel;
delivering a second gas stored at a second pressure to the mixing vessel so as to facilitate mixing of the first and second gases within the mixing vessel to form a gas mixture including the first and second gases; and
facilitating forced movement of the gas mixture including the first and second gases from the mixing vessel to the buffer tank utilizing a forcing gas that is at a pressure greater than the first pressure.

13. The method of claim 12, wherein the gas mixture is formed with a selected concentration of each of the first and second gases by delivering each of the first and second gases into the mixing vessel until a selected pressure is reached within the mixing vessel.

14. The method of claim 12, wherein the first pressure of the first gas is in the range of about 0.01 bar to about 100 bar.

15. The method of claim 12, wherein the first pressure of the first gas is in the range of about 0.1 bar to about 50 bar.

16. The method of claim 12, wherein the first pressure of the first gas is no greater than about 1 bar.

17. The method of claim 12, wherein the second pressure of the second gas is in the range of about 0.1 bar to about 300 bar.

18. The method of claim 12, wherein the second pressure of the second gas is in the range of about 1 bar to about 200 bar.

19. The method of claim 12, wherein the first gas is selected from the group consisting of carbon dioxide, silane, germane, phosphine, arsine, hydrogen selenide and hydrogen sulfide.

20. The method of claim 19, wherein the second gas is selected from the group consisting of hydrogen, helium and nitrogen.

21. The method of claim 12, wherein facilitating forced movement of the gas mixture including the first and second gases from the mixing vessel toward the buffer tank includes:
providing a sealing member disposed within the mixing vessel and configured to be movable within and between a first end and second end of the mixing vessel while maintaining a sealing engagement with interior wall surface portions of the mixing vessel; and
providing the forcing gas at the first end of the mixing vessel, wherein the forcing gas is provided at a third pressure that is greater than the first and second pressures so as to force the sealing member to move from the first end of the mixing vessel toward the second end of the mixing vessel and to force the gas mixture including the first and second gases from the second end of the mixing vessel and to the buffer tank.

22. The method of claim 21, further comprising:
generating a pressure differential within the mixing vessel, via a vacuum source connected with the first end of the mixing vessel, so as to pull the sealing member from the second end of the mixing vessel toward the first end of the mixing vessel and evacuate and draw the forcing gas from the mixing vessel toward the vacuum source.

23. The method of claim 12, wherein the second gas is the forcing gas that forces the gas mixture including the first and second gases to the buffer tank.

24. The method of claim 23, wherein the first gas is delivered to a first sub-chamber of the mixing vessel, the second gas is delivered to a second sub-chamber of the mixing vessel, and the forced movement of the gas mixture including the first and second gases from the mixing vessel toward the buffer tank includes:
providing an adjustable valve disposed between the first and second sub-chambers; and
manipulating the adjustable valve from a first position that isolates and prevents movement of gases between the first and second sub-chambers to a second position that facilitates fluid communication between the first and second sub-chambers such that the second gas forces the gas mixture including the first and second gases from the mixing vessel to the buffer tank.

25. The method of claim 12, further comprising:
evacuating gases from the mixing vessel, via a vacuum source connected with the mixing vessel, such that the mixing vessel has a pressure that is less than each of the first and second gases.

26. The method of claim 25, further comprising:
evacuating gases from the buffer tank via the vacuum source.

27. The method of claim 12, further comprising:
filtering the gas mixture including the first and second gases utilizing a filter disposed between the mixing vessel and the buffer tank.

28. The method of claim 12, further comprising:
facilitating further mixing of the gas mixture including the first and second gases utilizing a mixing unit disposed between the mixing vessel and the buffer tank.

29. The method of claim 12, further comprising:
delivering the gas mixture from the buffer tank to a process tool.

30. The method of claim 29, further comprising:
monitoring the pressure of the buffer tank during delivery of the gas mixture from the buffer tank to the process tool;
wherein the steps of delivering the first and second gases to the mixing vessel and facilitating forced movement of the gas mixture including the first and second gases from the mixing vessel to the buffer tank are repeated when the monitored pressure of the buffer tank is at or below a minimum pressure value.

31. The method of claim 30, wherein the gas mixture is delivered at a substantially continuous flow rate to the process tool during the repeating of the steps of delivering the first and second gases to the mixing vessel and facilitating forced movement of the gas mixture including the first and second gases from the mixing vessel to the buffer tank.

32. The method of claim 29, wherein the process tool is configured to process a semiconductor component.

33. A gas mixing and delivery system comprising:
means for storing a first gas at a first pressure;
means for storing a second gas at a second pressure;
a mixing vessel configured to receive the first and second gases from the means for storing the first gas and the means for storing the second gas;
a buffer tank connected to the mixing vessel so as to receive a gas mixture including the first and second gases delivered from the mixing vessel, the buffer tank being configured to connect with a process tool; and
a means for forming a gas mixture including the first and second gases within the mixing vessel and delivering the gas mixture to the buffer tank, wherein the means for forming and delivering the gas mixture includes a forcing gas that is at a pressure greater than the first pressure and that forces the gas mixture to the buffer tank.
